(19) United States
(12) Patent Application Publication
(10) Pub. No.: US 2022/0039300 A1
(43) Pub. Date: Feb. 3, 2022

(54) ELECTROMAGNETIC INTERFERENCE MANAGEMENT IN A POWER CONVERTER

(71) Applicant: GaN Force Corporation, HsinChu City (TW)

(72) Inventors: Michael D. Seeman, San Jose, CA (US); Loveday Haachitaba Mweene, Wylie, TX (US)

(21) Appl. No.: 16/944,518

(22) Filed: Jul. 31, 2020

(51) Int. Cl. H05K 9/00; H02M 1/44

(52) U.S. Cl. CPC H05K 9/0071; H02M 2001/0038; H02M 1/44

(57) ABSTRACT

One or more embodiments can comprise a method, including detecting, by a power converter comprising a processor, a feedback signal level based on based on an output condition of an error amplifier. The method can further comprise, based on the feedback signal level, setting, by the power converter, a combination of a switching frequency and a magnetizing current level, wherein the combination is selected to achieve an electromagnetic interference (EMI) level for the power converter that satisfies a first condition.

### TECHNICAL FIELD

This disclosure generally relates to embodiments for supplying power to electronic components, and more particularly to a power converter for supplying power with different switching frequencies.

### BACKGROUND

Power converters are used to convert between an available line (input) voltage and current and a desired load (output) voltage and current. Power converters can be configured to supply power with different characteristics, based on the requirements of electronic components, with these characteristics including, but not limited to, the switching frequency of the power supplied and the peak magnetizing current of the power supplied. One problem that can occur when converting power with a power converter, is an amount of electromagnetic interference (EMI) that can be caused by the converter. To address this interference an EMI filter can be applied to the power converter or input. Conventionally, switching frequencies were within particular ranges, and EMI filters could be employed that were a reasonable size to filter EMI for the power converter.

Modern components can be advantageously used with faster switching frequencies to provide benefits including a reduction in transformer and overall system size. Problems can occur however, when designing systems using power converters that generate switching frequencies that are faster than typically used with conventional systems. In different implementations of converters that use modern switching frequencies, the conventional approaches to EMI filtering do not provide solutions that meet system size and operating requirements.

### SUMMARY

The following presents a simplified summary of one or more of the embodiments of the present invention, in order to provide a basic understanding of the embodiments. This summary is not an extensive overview of the embodiments described herein, e.g., it is intended to neither identify key or critical elements of the embodiments nor delineate any scope of embodiments or the claims. A purpose of this summary is to present some concepts of the embodiments in a simplified form as a prelude to the more detailed description that is presented later. It will also be appreciated that the detailed description may include additional or alternative embodiments beyond those described in the Summary section.

Some of the disclosed systems and methods provide for a power converter, comprising a feedback signal generator for generating a feedback signal based on an output condition of an error amplifier. The power converter can further comprise a control component for selecting, based on the feedback signal, a switching frequency and a magnetizing current level for an output load of the power converter, wherein the switching frequency and the magnetizing current level are selected to achieve an electromagnetic interference (EMI) level for the power converter that satisfies a first condition.

In additional embodiments, the disclosed systems and methods can provide a method, comprising detecting, by a power converter comprising a processor, a feedback signal level based on based on an output condition of an error amplifier. In some implementations, the feedback signal can provide a measure of the necessary amount of power that the converter needs to provide to the output to bring the output voltage to a desired value.

The method can further comprise, based on the feedback signal level, setting, by the power converter, a combination of a switching frequency and a magnetizing current level, wherein the combination is selected to achieve an electromagnetic interference (EMI) level for the power converter that satisfies a first condition.

In other embodiments, a power converter can comprise an error amplifier for generating a command power signal. The power converter can further comprise a controller component, wherein in response to the command power, the controller component can select a switching frequency and a magnetizing current level for an output load of the power converter, wherein the switching frequency and the magnetizing current level are selected to achieve an electromagnetic interference (EMI) level for the power converter that satisfies a first condition.

### BRIEF DESCRIPTION OF THE DRAWINGS

Non-limiting embodiments of the subject disclosure are described with reference to the following figures, wherein like reference numerals refer to like parts throughout the various views unless otherwise specified:

FIG. 1 depicts a circuit diagram of a non-limiting, example power converter that can be implemented according to one or more embodiments described herein.

FIG. 2 depicts a block diagram of components of a non-limiting, example power converter, in accordance with one or more embodiments.

FIG. 3 depicts a more detailed block diagram of components of a non-limiting, example control component of the power converter of FIG. 2, in accordance with one or more embodiments.

FIG. 4 depicts a more detailed example of a controller IC of the power converter of FIG. 1, in accordance with one or more embodiments.

FIGS. 5A, 5B, and 5C depict a chart of example relationships between different characteristics of a power converter, in accordance with one or more embodiments.

FIG. 6 depicts an example implementation of the control law approach described above, in accordance with one or more embodiments.

FIG. 7 depicts a chart of a high-level sketch of an example EMI scan, in accordance with one or more embodiments.

FIG. 8 illustrates an example flow diagram for a method that can facilitate converting input power to higher switching frequencies with smaller EMI filters than other approaches, in accordance with one or more embodiments.

### DETAILED DESCRIPTION

Aspects of the subject disclosure will now be described more fully hereinafter with reference to the accompanying drawings in which example embodiments are shown. In the following description, for purposes of explanation, numerous specific details are set forth in order to provide a thorough understanding of the various embodiments. However, the subject disclosure may be embodied in many different forms and should not be construed as limited to the example embodiments set forth herein.

Reference throughout this specification to “one embodiment,” “an embodiment,” or “one or more embodiments” can be an indication that a particular feature, structure, or characteristic described in connection with the embodiment is included in at least one embodiment. Thus, the appearances of the phrase “in one embodiment,” “in an embodiment,” and “in one or more embodiments” in various places throughout this specification are not necessarily all referring to the same embodiment. Furthermore, the particular features, structures, or characteristics may be combined in any suitable manner in one or more embodiments.

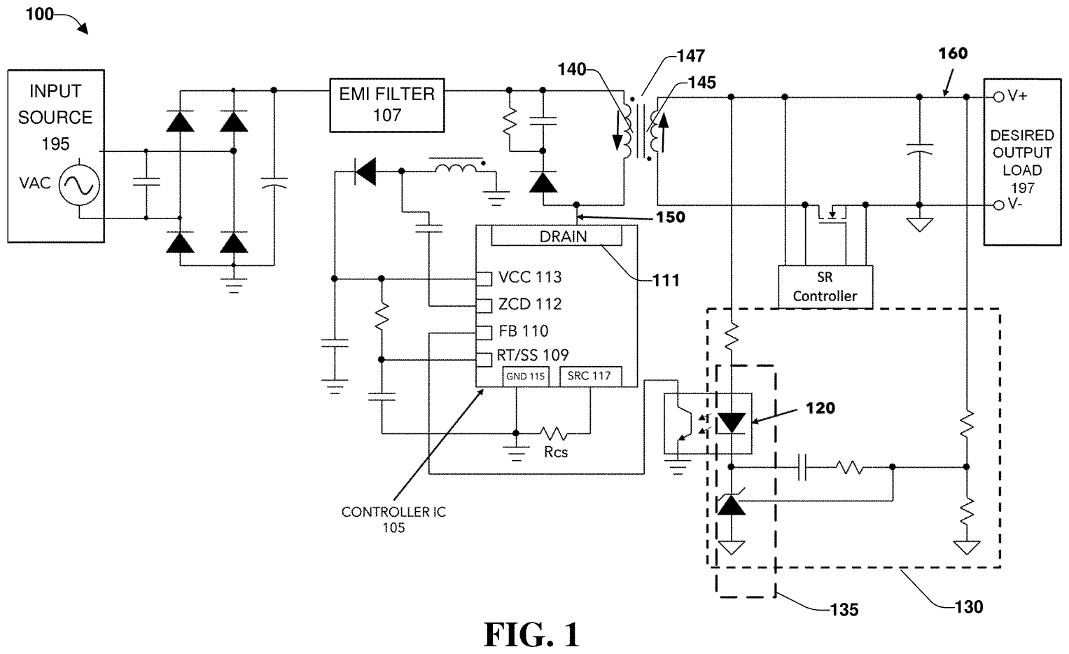

FIG. 1 depicts a circuit diagram of non-limiting, example power converter 100 that can be implemented according to one or more embodiments described herein. For purposes of brevity, description of like elements and/or processes employed in other embodiments described below, is omitted.

As depicted, power converter 100 can receive input source 195 and, in accordance with one or more embodiments, with EMI filter 107, can be discharged as desired output load 197. As depicted, example power converter 100 can include controller IC 105, compensation circuit 130, and optoisolator 120. In different implementations, controller IC 105 can include ground (GND) 115, source (SRC) 117, a pin for common collector voltage (VCC) 113, a pin for zero crossing detector input (ZCD) 112, a pin for timing resistor/soft start (RT/SS) 109, a pin to receive feedback signal (FB) 110 from optoisolator 120 based on output from error amplifier 135 of compensation circuit 130, and drain 111. One having skill in the relevant art(s), given the description herein, would appreciate that controller IC 105 can, in accordance with different embodiments, have different combinations of input and output elements. It should be noted that, as depicted, error amplifier 135 is a part of compensation circuit, but one having skill in the relevant art(s), given the description herein, will appreciate that many different implementation approaches can indicate output conditions used to generate FB 110.

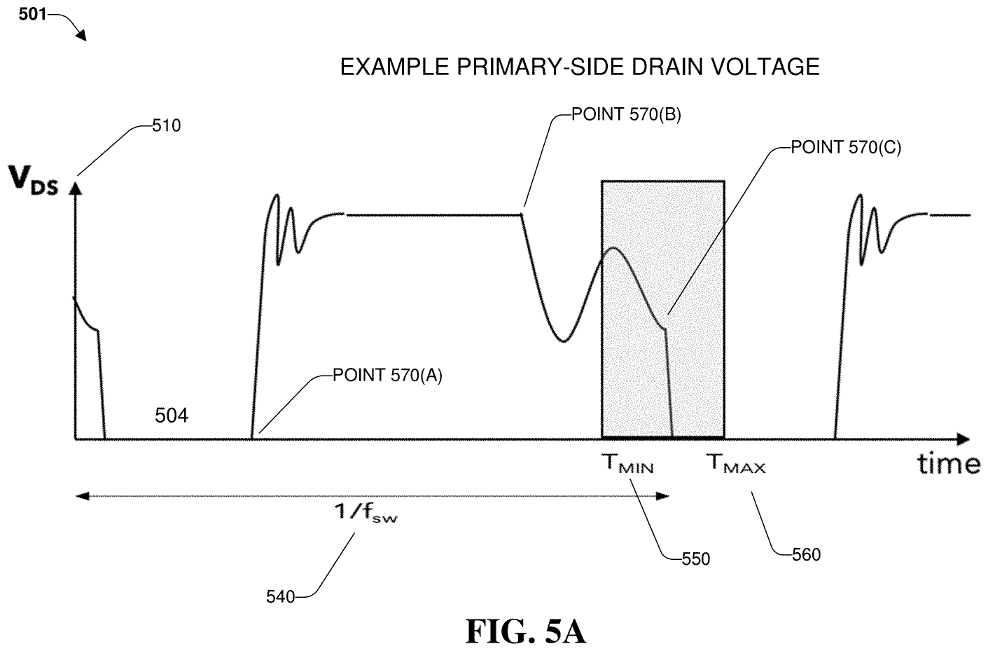

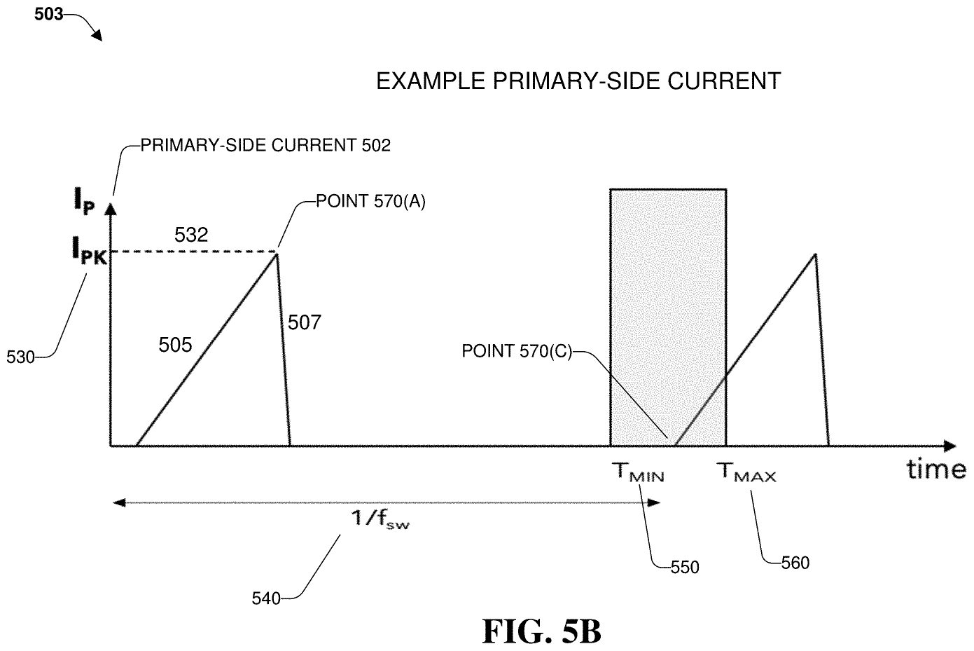

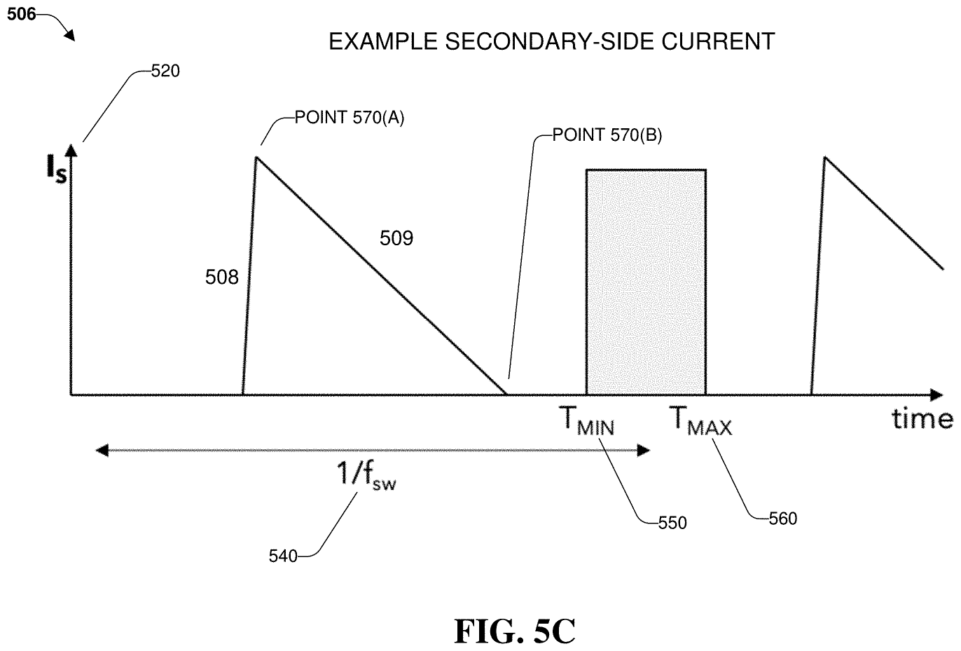

As described further with FIGS. 5A-5C below, FIG. 1 depicts transformer 147 and several points where different voltage and current values associated with embodiments can be measured. For example, primary-side drain voltage can be measured at measurement point 150, e.g., the drain 111 voltage of controller IC 105. In another example, with transformer 147, secondary-side current corresponds to the current of desired output load 197, and secondary-side current can be measured at a secondary winding of transformer 147, at measurement point 145, and primary side drain current can be measured at a primary winding of transformer 147, e.g., at measurement point 140, with this value corresponding to magnetizing current, in one or more embodiments.

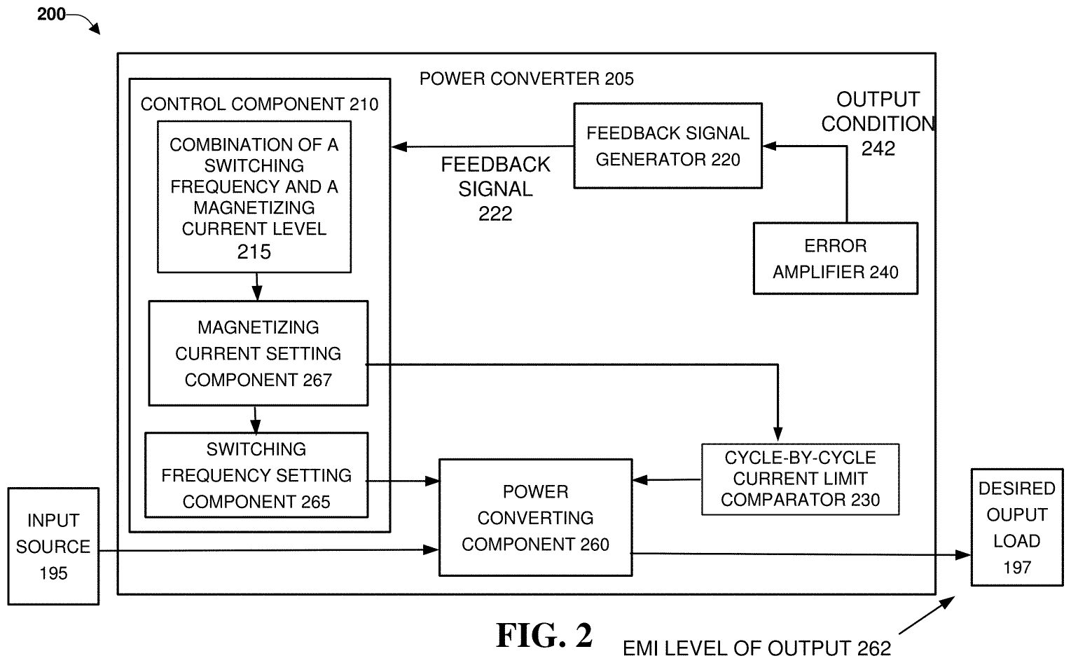

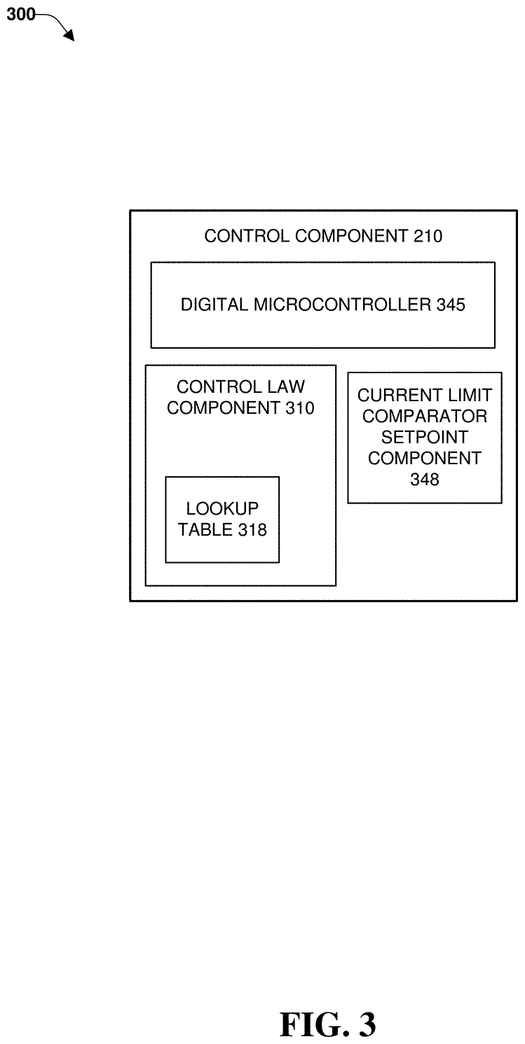

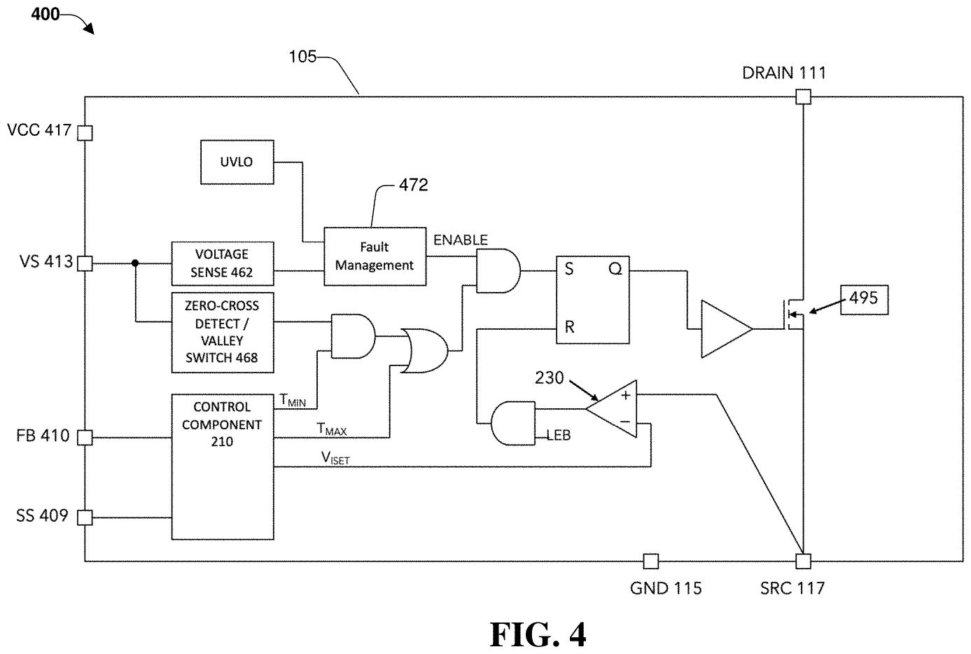

Additional details regarding the structure and functions of controller IC 105 are provided further herein, e.g., with component diagrams at FIGS. 2 and 3, and an example, detailed circuit diagram provided with FIG. 4. In one or more embodiments, compensation circuit 130 can be also used to generate feedback signal (FB) 110 received by a control component of controller IC 105 (e.g., discussed with FIG. 2 below).

In the non-limiting example depicted in FIG. 1, power converter 100 is a flyback converter that can be configured to convert from an offline voltage (e.g. 120 VAC) to a desired output voltage, e.g. 20V, 2.25 A for a laptop charger. As would be appreciated by one having skill in the relevant art(s), given the description herein, there are numerous power converter topologies, with numerous configurations which can benefit from the approaches described by one or more embodiments herein. In the example depicted in FIG. 1, many aspects of this topology are not labeled or discussed herein, but would be apparent to one having skill in the relevant art(s), given the description herein.

FIGS. 2 and 3 depict block diagrams of an example implementation of one or more embodiments of an example system 200 for a power converter 205. For purposes of brevity, descriptions of like elements and/or processes employed in other embodiments are omitted. As depicted in FIG. 2, power converter 205 includes error amplifier 240, feedback signal generator 220, control component 210, power converting component 260, switching frequency setting component 265, magnetizing current setting component 267, cycle-by-cycle current limit comparator 230, and other components that can be used to implement one or more embodiments described herein. In one or more embodiments, as depicted, control component 210 can include switching frequency setting component 265 and magnetizing current setting component 267.

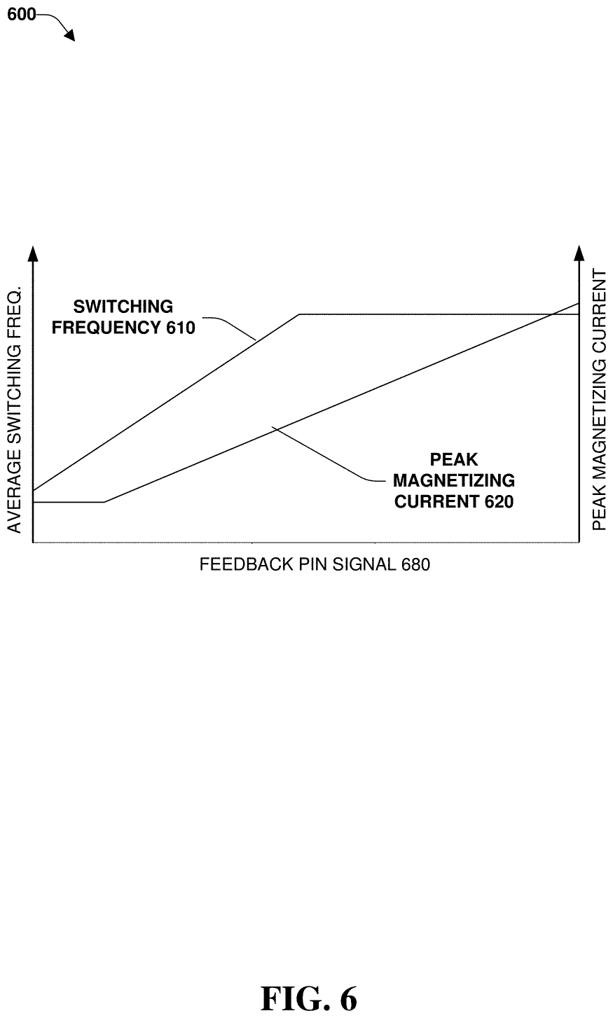

In one or more embodiments, error amplifier 240 can amplify output condition 242 for feedback signal generator 220. Feedback signal generator 220 can generate feedback signal 222 to provide to control component 210, which can use feedback signal 222 to select a combination of a switching frequency and a magnetizing current level 215. Based on this combination 215, control component 210 can utilize switching frequency setting component 265 and magnetizing current setting component 267 to set these values for power converting component 260. Power converting component 260 can modify input source 195 to be desired output load 197 having a frequency and magnetizing current level that generates EMI level 262. As discussed further below with FIGS. 5A-5C and 6, cycle-by-cycle current limit comparator 230 can monitor the resulting magnetizing current of desired output load 197 and adjust the operation of one or more embodiments accordingly.

FIG. 3 depicts a block diagram of an example implementation of one or more embodiments of control component 210 of controller IC 105 of power converter 205. For purposes of brevity, description of like elements and/or processes employed in other embodiments is omitted. In one or more embodiments, control component 210 can include, as depicted, digital microcontroller 345, control law component 310, and current limit comparator setpoint component 348. Control law component can include lookup table 318 for use selecting the combination of a switching frequency and magnetizing current level 215.

In one or more embodiments, control component 210 (e.g., utilizing microcontroller 345), can detect feedback signal 222 based on output condition 242 provided by error amplifier 240. Based on feedback signal 222, power converting component 260 can utilize lookup table 318 to select the combination of a switching frequency and magnetizing current level 215, with the combination 215 being selected to achieve an electromagnetic interference (EMI) level 262 that satisfies a condition, e.g. is equal to or below a desired level of EMI. Once selected, the combination of a switching frequency and magnetizing current level 215 can be set for power converting component 260 by switching frequency setting component 265 and magnetizing current setting component 267, respectively.

One approach that can be used by one or more embodiments to select the combination of a switching frequency and magnetizing current level 215 is to employ lookup table 318 of control law component 310, with lookup table 318 values set based on a desired EMI level 262. In another approach, current limit comparator setpoint component 348 can select a setpoint to provide to cycle-by-cycle current limit comparator 230 for selection of magnetizing current, e.g., a maximum secondary-side current for output.

FIG. 4 depicts a more detailed example 400 of a power converter (e.g., power converter 100 of FIG. 1), in accordance with one or more embodiments. For purposes of brevity, description of like elements and/or processes employed in other embodiments is omitted.

As depicted in FIG. 4, controller IC 105 can include, ground (GND) 115, source (SRC) 117, a pin for VCC 417, a pin for voltage sense (VS) 413, voltage sense 462, zero cross detect/valley switch 468, and control component 210, with a pin for soft start (SS) 409. Controller IC 105 can further include fault management component 472, cycle-by-cycle current limit comparator 230, and transistor 495 with drain 111. In an exemplary embodiment, transistor 495 can be a depletion mode, metal-insulator-semiconductor diode, high-electron-mobility transistor (d-mode MIS-D HEMT), but it should be noted that other types of transistors can be used with different implementations of embodiments described and suggested by the disclosure herein.

Typical silicon-based flyback converters operate at a switching frequency below 150 kHz. One or more embodiments can examine high-frequency energy from an input line into power converter 100 e.g., these signals falling, for example, between 150 kHz and 30 MHz. In implementations with a sub-150 kHz design, higher-order harmonics of the switching frequency can fall into this EMI band. In one or more embodiments, because the amplitude (strength) of harmonics can be less than the fundamental, the necessary size of an EMI filter for a particular application can be reduced, while still maintaining line energy below required limits.

One or more embodiments can provide benefits when a gallium-nitride (GaN)-based transistor is used for transistor 495. Use of GaN based transistors can facilitate faster switching frequencies, which can reduce transformer and overall system size as compared to other types of transistors. For example, a GaN-based flyback design may switch up to 500 kHz, and with these high-frequency designs, the energy at the fundamental switching frequency can lie within the EMI band of interest. Based on these characteristics, transistor 495 may require a larger EMI filter than traditional low-frequency designs. In some implementations of embodiments described herein however, higher switching frequencies can be handled, and as switching frequency increases beyond the 150 kHz threshold, the EMI filter required can tend to become smaller, e.g., because at higher switching frequencies EMI can require less overhead to filter out.

In an exemplary embodiment, the power converter 100 described herein can be implemented for and off-line flyback converter operated in a form of discontinuous conduction mode (DCM), where the magnetizing current returns to zero during each switching period. In this example, there are two primary degrees of freedom of the operation of this converter, including but not limited to, a switching frequency and a magnetizing current, e.g., a peak magnetizing current. In one or more embodiments, the combination of these two elements can satisfy different load conditions. To assess operating conditions of power converter 100, an error amplifier 240 (e.g., similar to error amplifier 135 of FIG. 1) and feedback signal generator 220 (e.g., using optoisolator 120 of FIG. 1) can be used to ensure the load conditions are met. Further, a control component (e.g., implementing a custom control law circuit) can be used to determine the desired switching frequency and peak magnetizing current as a function of the feedback signal. There is an additional degree of freedom in this control approach, as there are two variables and one equation (to match the load conditions).

As described herein, one or more embodiments can facilitate power conversion to higher switching frequencies while mitigating EMI problems. One approach that can be used is the measure the amount of EMI with a given switching frequency and magnetizing current and set one or both of these characteristics so as to facilitate the use of an EMI filter of a particular size. One approach that can be used by control law component 310 is to apply a control law having one or more degrees of freedom.

For example, in one or more embodiments, control law component 310 can receive a feedback signal 222 (e.g., from feedback signal generator 220) for selecting, based feedback signal 222, a switching frequency and magnetizing current level 215 for an output load of the power converter, with, in some embodiments, the combination of switching frequency and magnetizing current level 215 are selected to achieve an EMI for the power converter that satisfies a first condition. In some embodiments, the first condition comprises the EMI level being in a state in relation to a first threshold, e.g., at a level below the threshold, also with an EMI level minimized.

In a variation of this approach, one or more embodiments, the switching frequency and the magnetizing current level 215 can select a combination within a range of switching frequencies relevant to filtering EMI of the power converter, e.g., with EMI ranging from 150 kHz to 30 MHz, the higher end of the frequency range is generally considered easier to filter out with a physically smaller filter, and some embodiments that select higher switching frequencies can require less overhead to filter EMI from the output of the power converter. Thus, some embodiments can facilitate using a smaller EMI filter for the power converter, and this smaller EMI filter size can be considered an advantageous result that can be combined with other factors described and suggested herein that influence the selection of the switching frequency and magnetizing current.

As described further below, one or more embodiments can advantageously select a combination of switching frequency and magnetizing current that reduces (e.g., minimizes) EMI, while having additional predicted benefits based on the combination. For example, in one or more embodiments, the selected combination of switching frequency and the magnetizing current level 215 can be further selected to achieve a relationship of a stability level for the power converter to a threshold, e.g., to have a stability above a particular level, up to the point of having a stability above a desired level, given the other considerations described and suggested herein that can be used to select the combinations of EMI level, switching frequency and magnetizing current. Considered in greater detail, different combinations of switching frequency and magnetizing current can result in different amounts of power produced by the power converter, and with these different amounts of power produced, other results can occur, e.g., a gain amount can be selected for the power output. Depending upon the levels and stability of gain settings utilized, the stability of the power converter can be affected. Thus, in one or more embodiments, the combinations of switching frequencies and magnetizing currents selected can be influenced by additional factors described and suggested herein.

In one or more additional embodiments, to reduce or minimize the EMI filter size utilized to satisfy EMI requirements of power converter 100, feedback signal (FB) 110 can be used to adjust (e.g., reduce) peak current before a switching frequency is reduced from a peak value. This relationship between factor described and suggested above (e.g., switching frequency, magnetizing current, and EMI filter size), and the use of these characteristics to affect the operation of power converter 100, can be termed the control law applied to power converter 100.

One approach that can be used to achieve one or more of the above-described functions, is to provide to controller IC 105 with a measurement of a level of a feedback signal 222 generated by the operation of power converter 100. One approach to providing this measure to control component 210 is by operation of an error amplifier 240, e.g., referring to FIG. 1, output from error amplifier 135 of compensation circuit 130 can be used to generate feedback signal 222. In one or more embodiments, error amplifier 240 can provide input to feedback signal generator 220 to generate feedback signal 410 to be received by control component 210, referring to FIG. 2, feedback signal (FB) 110 can be generated by optoisolator 120 based on output from error amplifier 135 of compensation circuit 130.

In different embodiments, this feedback signal can be comprised of one or more of a current or a voltage level, e.g., with control law component 310 receiving feedback signal (FB) 410 and decoding one or both of the current or voltage level of the FB 410 to determine a level of EMI generated by power converter 100. In one or more embodiments, FB 410 can be used as an input in a determination, by control law component 310, to alter one or both of the switching frequency or magnetizing current of power converter 100.

In one or more embodiments and in some circumstances, a physically-smaller EMI filter 107 can be advantageous over a larger EMI filter, and in one or more embodiments, the size of an EMI filter that can advantageously satisfy EMI requirements for a power converter can be decreased as switching frequency increases, e.g., as noted above, above 150 kHz.

One approach that can be used to select or alter the switching frequency and/or magnetizing current of power converter 100, is to use error amplifier 240 to provide of an output voltage that can be used to achieve an optimal EMI filter size, e.g., output condition 242. This output condition 242 can be generated based on a combination of a desired EMI level 262 and the current output load level, e.g., a load current required for a component powered by power converter 100. As discussed above with FIG. 2, feedback signal generator 220 can use output condition 242 to generate feedback signal 222 (e.g., feedback signal 410 in FIG. 4), and control law component 310 can determine an optimal switching frequency and optimal current value as a function of feedback signal 222.

One approach that can be used by one or more embodiments to select different configurations of power converter 100 is to utilize lookup table 318 of control component 210 to select a switching frequency and magnetizing current based on different EMI levels comprised in FB 410. In one or more embodiments, the value resulting from lookup table 318 can be a range of different values, e.g., a minimum and maximum switching frequency that can be combined with other configuration settings to achieve the requirements of power converter 100.

FIGS. 5A-5C respectively depict charts 501, 503, and 506 illustrating example relationships between different waveforms associated with power converter 100, in accordance with one or more embodiments. For purposes of brevity, description of like elements and/or processes employed in other embodiments is omitted. It should be noted that, in the discussion below, several points (e.g., points 570A-5C) have been marked on charts 501, 503, 506, and these points are intended to be general reference points for different events associated with embodiments, i.e., not exact time points.

As depicted, chart 501 of FIG. 5A depicts an example chart of primary-side drain voltage over a time period, in accordance with one or more embodiments. In this example, the X-axis corresponds to time, and the Y-axis corresponds to the primary-side drain voltage of one or more embodiments, e.g., drain 111 voltage of transistor 495 of controller IC 105, measured at measurement point 150. As depicted, chart 503 of FIG. 5B depicts an example chart of primary side drain current over a time period, in accordance with one or more embodiments. In this example, the X-axis corresponds to time, and the Y-axis corresponds to primary side drain current, e.g., as noted above with FIG. 1, measured at measurement point 140 of transformer 147. As depicted, chart 506 of FIG. 5C depicts an example chart of secondary-side current over a time period, in accordance with one or more embodiments. In this example, the X-axis corresponds to time, and the Y-axis corresponds to secondary-side current, e.g., as noted above with FIG. 1, at measurement point 145 of transformer 147.

In one or more embodiments, as shown in FIGS. 5A-5B, primary-side current 502 can ramp up as shown in curve 505 while the primary-side FET is on. Also, primary-side current 502 can step to zero at point 570(A) like curve 507 when the primary-side FET turns off. As depicted, primary-side FET drain voltage 510 can be near-zero when the primary-side FET is on, and begins to increase at point 570(A) to Vᵢₙ+Vₒᵤₜ*np/ns (transformer turns ratio) when the primary-side FET drain voltage 510 is flowing, and as depicted in FIGS. 5A and 5C, when secondary-side current stops conducting at point 570(B), the primary-side FET drain voltage 510 can ring at a level near to the input voltage of input source 195.

In one or more embodiments, secondary side current 520 can step high up to point 570(A) like curve 508 when primary-side FET (e.g., transistor 495) is turned-off and secondary side current 520 can ramp down to zero like curve 509, e.g., during this time, energy is transferred from the transformer 147 to desired output load 197. A magnetizing current limit 532 for magnetizing current 502 can be set by the control law, and when the magnetizing current 502 reaches magnetizing current limit 532 at point 570(A), control component 210 can turn off the primary-side FET (e.g., transistor 495), in accordance with one or more embodiments.

In one or more embodiments, switching period 540 can represent the time from one turn-on edge of the primary-side FET to the following turn-on edge, with the switching frequency being the reciprocal of this period. In one or more embodiments, minimum switching period Tₘᵢₙ 550 can be set by the control law, with the reciprocal of switching period being the maximum switching period Tₘₐₓ 560 that can be set by the control law applied. For example, at switching point 570(C), control component 210 can turn on the primary-side FET (e.g., transistor 495) during the first detected valley (e.g., point 570(C)) inside the window between Tₘᵢₙ 550 and Tₘₐₓ 560.

FIG. 6 depicts chart 600 of an example implementation of the control law approach described above, in accordance with one or more embodiments. For purposes of brevity, description of like elements and/or processes employed in other embodiments is omitted. Chart 600 includes a secondary Y-axis corresponds to peak magnetizing current 620, and a primary Y-axis corresponds to switching frequency 610. As noted above, one or more embodiments can affect the EMI generated by power converter 100 by using control component 210 to select combinations of peak magnetizing current 620 and switching frequency 610. As depicted, chart 600 describes a control law definition chart, with example feedback pin signal 680 (e.g., received by FB 110) that can be generated to set combinations of peak magnetizing current 620 and switching frequency 610, e.g., a signal representing how much energy one or more embodiments deliver to the output.

In one or more embodiments, the one or more functions depicted in FIG. 6 can be implemented in software or hardware, as control component 210. One function that can be utilized can determine a desired peak magnetizing current and switching frequency (minimum & maximum) as a function of the feedback pin signal 680 as feedback pin current or feedback pin voltage. It should be noted that, depending upon implementations of one or more embodiments, the feedback signal can be encoded in either current or voltage.

As depicted in this example, in one or more embodiments, peak magnetizing current 620 (e.g., magnetizing current limit 532) is a current which can compared (e.g., compared by cycle-by-cycle current limit comparator 230) with the current through the current-sense resistor (e.g., the current measured at peak magnetizing current measurement point 150), and both can be represented by (representational) voltages to determine whether the set current selected by the system corresponds to the actual current produced. Referring back to FIGS. 5A-5C, when magnetizing current 502 reaches magnetizing current limit 532 (e.g., peak magnetizing current 620 set by the control law), transistor 495 is turned off and secondary side current 520 can ramp down to zero like curve 509, with energy being transferred from the transformer 147 to desired output load 197.

In this example, the output of one or more embodiments plotted as switching frequency 610 can be used to control the switching frequency of power converter 100, e.g., at desired output load 197 point. In a variation of this example, the switching frequency 610 output can be used, for example, with additional processing, e.g. through another relationship such as minimum switching frequency determined as a percentage, such as 60%, of maximum switching frequency.

It should be particularly noted that one or more embodiments include implementations where, as feedback pin signal 680 increases (e.g., indicating a lower output load), as depicted, peak magnetizing current 620 decreases, e.g., an inverse proportional relationship can exist within the selected combination of frequency and magnetizing current. Other relationships of note that can be measured and used to control one or more embodiments include, as shown in FIG. 6, having the desired load current decrease as the feedback pin signal 680 increases. It would be appreciated by one having skill in the relevant art(s), given the description herein, that this relationship between desired load current and feedback pin signal 680 could be opposite as well. Other relationships of note include, but are not limited to, switching frequency 610 decreasing as the feedback pin signal 680 increases, and peak magnetizing current 620 decreasing as feedback pin signal 680 increases. Additional characteristics of the one or more functions depicted in FIG. 6 include that, in some implementations, switching frequency 610 can stays well above 150 kHz at peak magnetizing current, and peak magnetizing current can reduce to a lower level before switching frequency 610 decreases to 150 kHz.

Returning to the functions of one or more embodiments described with FIGS. 1 and 2 above, it should be noted that shape of one or both of peak magnetizing current 620 and switching frequency 610 can facilitate the minimizing of EMI filter 107 size and the implementation of the target controller, e.g., control component 210. One approach to facilitating the functions described herein manages the effective gain of the applied control law (e.g., a change in output current as a function of a change in feedback pin signal 680) such that a fixed feedback compensation will maintain a stable overall control loop with the desired stability metrics (e.g. phase margin). Example advantages that can result from the implementation some of the approaches described with FIG. 6 include facilitating the implementation of a high-frequency power converter with both a minimal power magnetic size as well as a minimal size of EMI filter 107, with this combination being potentially difficult to implement by conventional methods.

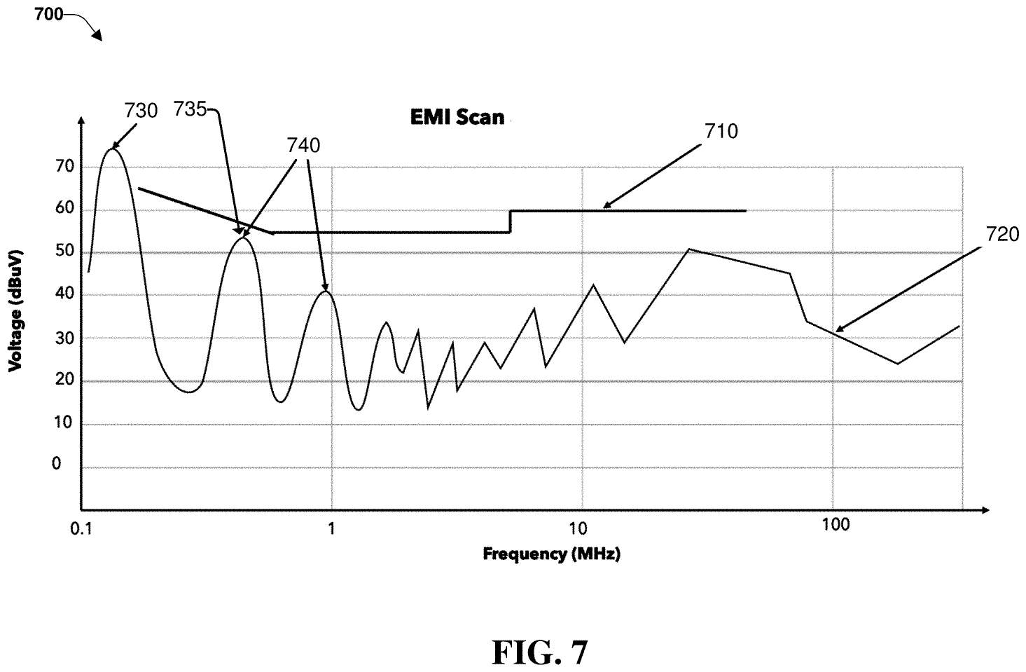

FIG. 7 depicts a chart 700 of a high-level sketch of an example EMI scan, in accordance with one or more embodiments. For purposes of brevity, description of like elements and/or processes employed in other embodiments is omitted.

In example operating conditions of power converter 205, conducted EMI spectrum can be between 150 kHz and 30 MHz, e.g., because currently, FCC part 15 class B and other standards specify the maximum tested conducted EMI for power supplies as 30 MHz. In the implementation of one or more embodiments, a maximum EMI limit can be provided by this 30 MHz standard, e.g., measured spectrum 720 can be limited to this maximum one or more measured frequencies.

As depicted in FIG. 7, measured spectrum 720 can be EMI measured according to the method specified by relevant standard(s). In a simplified example of measuring EMI spectrum that can be used by one or more embodiments, the amplitude of the signal at each frequency in the range can be measured, and in some circumstances, this amplitude is measured at least across frequencies of interest (150 kHz to 30 MHz), not extended as shown here for reference. In an example, maximum EMI limit 710 corresponds to maximum limit permitted for operation of the powered device, and based on operation of one or more embodiments, measured spectrum 720 (e.g., the results of the use of one or more embodiments) falls below, maximum EMI limit 710 across all measured frequencies

Referring to example points in chart 700, in or more embodiments, an EMI signature can be at the fundamental switching frequency, and in some implementations, if switching frequency 610 falls below maximum EMI limit 710 (e.g., below maximum limit of 150 kHz at point 735), the magnitude of the EMI signature is not considered when testing for EMI, e.g., with EMI tested at EMI level of output 262 discussed with FIG. 2. Alternatively, in one or more embodiments, when switching frequency 610 is above maximum EMI limit 710 (e.g., at point 730), the magnitude of EMI signature can be considered when testing for EMI, e.g., filtering this peak to meet the implementation limits, e.g., at point 735. In additional examples, harmonics 740 can, in accordance with one or more embodiments, fall below the EMI limit when switching frequency exceeds 150 kHz, e.g., harmonics being typically 3-5 at times the frequency switching rate.

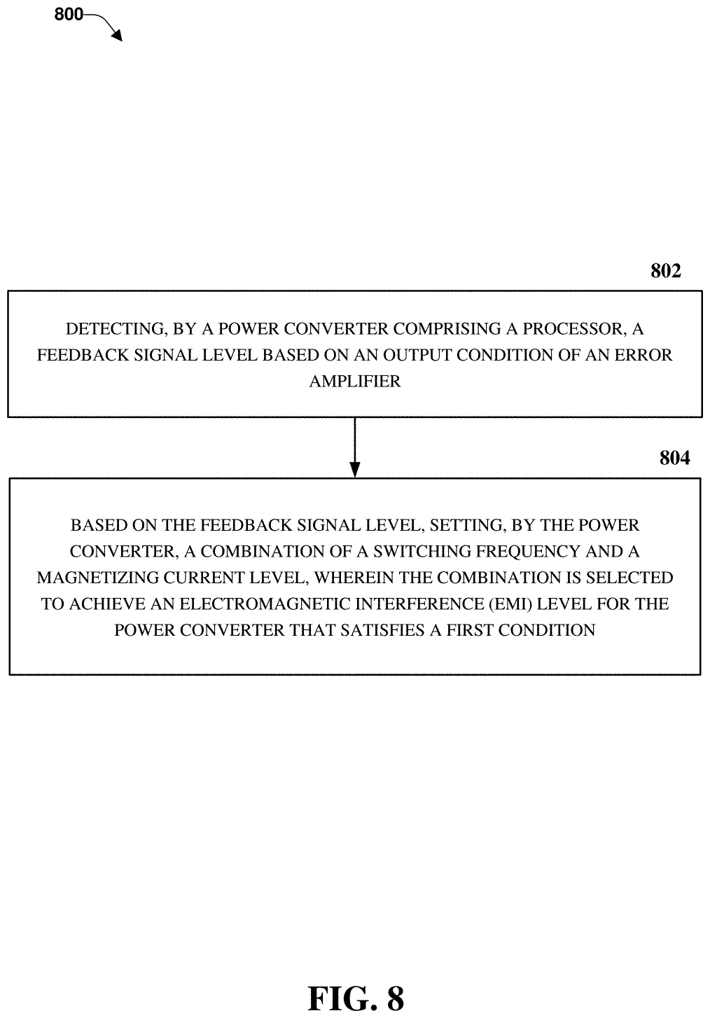

FIG. 8 illustrates an example flow diagram for a method 800 that can facilitate converting input power to higher switching frequencies with smaller EMI filters 107 than other approaches, in accordance with one or more embodiments. For purposes of brevity, description of like elements and/or processes employed in other embodiments is omitted.

In this example, method 800, that can be used by a power circuit, is provided, the method comprising steps 802-804 described below. At step 802, the method can comprise detecting, by a power converter comprising a processor, a feedback signal level based on an output condition of an error amplifier. At step 804, the method can further comprise, based on the feedback signal level, setting, by the power converter, a combination of a switching frequency and a magnetizing current level, with the combination being selected to achieve an electromagnetic interference (EMI) level for the power converter that satisfies a first condition.

While the various embodiments are susceptible to various modifications and alternative constructions, certain illustrated implementations thereof are shown in the drawings and have been described above in detail. It should be understood, however, that there is no intention to limit the various embodiments to the specific forms disclosed, but on the contrary, the intention is to cover all modifications, alternative constructions, and equivalents falling within the spirit and scope of the various embodiments. Moreover, while the various embodiments are susceptible to various modifications and alternative constructions, certain illustrated implementations thereof are shown in the drawings and have been described above in detail. It should be further understood, however, that there is no intention to limit the various embodiments to the specific forms disclosed, but on the contrary, the intention is to cover all modifications, alternative constructions, and equivalents falling within the spirit and scope of the various embodiments.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

What has been described above includes examples of the embodiments of the subject disclosure. It is, of course, not possible to describe every conceivable combination of configurations, components, and/or methods for purposes of describing the claimed subject matter, but it is to be appreciated that many further combinations and permutations of the various embodiments are possible. Accordingly, the claimed subject matter is intended to embrace all such alterations, modifications, and variations that fall within the spirit and scope of the appended claims. While specific embodiments and examples are described in subject disclosure for illustrative purposes, various modifications are possible that are considered within the scope of such embodiments and examples, as those skilled in the relevant art can recognize.

As used in this application, the terms “component,” “module,” “device” and “system” are intended to refer to analog circuitry or computer-related entity, comprising at least one of analog hardware, digital hardware, software or firmware. As one example, a component or module can be, but is not limited to being, a process running on a processor, a processor or portion thereof, a hard disk drive, multiple storage drives (of optical and/or magnetic storage medium), an object, an executable, a thread of execution, a program, and/or a computer. By way of illustration, both an application running on a server and the server can be a component or module. One or more components or modules scan reside within a process and/or thread of execution, and a component or module can be localized on one computer or processor and/or distributed between two or more computers or processors.

As used herein, the term to “infer” or “inference” refer generally to the process of reasoning about or inferring states of the system, and/or environment from a set of observations as captured via events, signals, and/or data. Inference can be employed to identify a specific context or action, or can generate a probability distribution over states, for example. The inference can be probabilistic—that is, the computation of a probability distribution over states of interest based on a consideration of data and events. Inference can also refer to techniques employed for composing higher-level events from a set of events and/or data. Such inference results in the construction of new events or actions from a set of observed events and/or stored event data, whether or not the events are correlated in close temporal proximity, and whether the events and data come from one or several event and data sources.

In addition, the words “example” or “exemplary” is used herein to mean serving as an example, instance, or illustration. Furthermore, the word “exemplary” and/or “demonstrative” is used herein to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent exemplary structures and techniques known to those of ordinary skill in the art.

As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

In addition, while an aspect may have been disclosed with respect to only one of several embodiments, such feature may be combined with one or more other features of the other embodiments as may be desired and advantageous for any given or particular application. Furthermore, to the extent that the terms “includes,” “including,” “has,” “contains,” variants thereof, and other similar words are used in either the detailed description or the claims, these terms are intended to be inclusive in a manner similar to the term “comprising” as an open transition word without precluding any additional or other elements.

1. A power converter, comprising:
a feedback signal generator for generating a feedback signal based on an output condition of an error amplifier; and
a control component for changing, based on the feedback signal, a switching frequency to a different switching frequency and a magnetizing current level to a different magnetizing current level for an output load of the power converter, wherein the different switching frequency and the different magnetizing current level are selected to achieve an electromagnetic interference (EMI) level for the power converter that satisfies a first condition.

2. The power converter of claim 1, wherein the first condition comprises the EMI level being in a state in relation to a first threshold.

3. The power converter of claim 2, wherein the first condition comprises the EMI level being below the first threshold.

4. The power converter of claim 1, wherein the different switching frequency and the different magnetizing current level are further selected to achieve the EMI level that satisfies the first condition within a range of switching frequencies relevant to filtering EMI of the power converter.

5. The power converter of claim 1, wherein the different switching frequency and the different magnetizing current level are further selected to achieve a relationship of a stability level for the power converter to a second threshold.

6. The power converter of claim 1, wherein the feedback signal comprises at least one of a current level or a voltage level.

7. The power converter of claim 1, wherein the control component comprises a lookup table for selecting the different switching frequency based on the feedback signal.

8. The power converter of claim 1, wherein the control component comprises a setpoint for a cycle-by-cycle current limit comparator, and wherein the cycle-by-cycle current limit comparator controls the magnetizing current level.

9. The power converter of claim 1, wherein the control component comprises at least one of analog hardware, digital hardware, software, or firmware.

10. The power converter of claim 1, wherein the magnetizing current level comprises a peak magnetizing current level.

11. The power converter of claim 1, wherein the control component comprises a digital microcontroller.

12. A method, comprising:
detecting, by a power converter comprising a processor, a feedback signal level based on an output condition of an error amplifier; and
based on the feedback signal level, changing, by the power converter, a combination of a switching frequency and a magnetizing current level to a combination of a different switching frequency and a different magnetizing current level, wherein the combination of the different switching frequency and the different magnetizing current level is selected to achieve an electromagnetic interference (EMI) level for the power converter that satisfies a first condition.

13. The method of claim 12, wherein the first condition comprises the EMI level being below a selected maximum level.

14. The method of claim 12, wherein the different switching frequency and the different magnetizing current level are further set to maintain a stability level for the power converter at a set stability level.

15. The method of claim 12, wherein the different switching frequency and the different magnetizing current level are further set to increase a stability level for the power converter above a minimum stability level.

16. The method of claim 12, wherein the different switching frequency of the combination is selected as equal to or above 150 kilohertz.

17. The method of claim 12, wherein the combination of the different switching frequency and the different magnetizing current level is selected to achieve the EMI level for a selected harmonic of a fundamental switching frequency.

18. The method of claim 12, wherein reducing or maintaining the electromagnetic interference level includes reducing or maintaining the EMI level for a selected harmonic of a fundamental switching frequency.

19. A power converter, comprising:
an error amplifier for generating a command power signal; and
a controller component, wherein in response to a command power, the controller component changes, for an output load of the power converter, a switching frequency to a different switching frequency and a magnetizing current level to a different magnetizing current level, wherein the different switching frequency and the different magnetizing current level are selected to achieve an electromagnetic interference (EMI) level for the power converter that satisfies a first condition.

20. The power converter of claim 19, wherein the first condition comprises the EMI level being below a first threshold.
